(19) United States
(12) Patent Application Publication
(10) Pub. No.: US 2006/0176060 A1
(43) Pub. Date: Aug. 10, 2006

(54) Method and circuit arrangement for the detection of ground faults on electronic trips for low-voltage circuit breakers comprising serially connected measuring amplifiers

(76) Inventors: Andreas Pancke, Berlin (DE); Ilka Redmann, Falkensee (DE); Wolfgang Röhl, Berlin (DE)

Correspondence Address: HARNESS, DICKEY & PIERCE, P.L.C., P.O.BOX 8910, RESTON, VA, 20195, US

(21) Appl. No.: 10/571,565

(22) PCT Filed: Aug. 24, 2004
(86) PCT No.: PCT/DE04/01906

§ 371 Date: Mar. 10, 2006

(30) Foreign Application Priority Data
Sep. 11, 2003 (DE) 103 42 599.3

(51) Int. Cl. G01R 31/14

(52) U.S. Cl. 324/510

(57) ABSTRACT

One problem during the detection of ground faults resides in the fact that the measuring amplifiers have a great amount of tolerance regarding the amplification factor thereof, resulting in a substantial error when errors are handled by means of software. According to the disclosure, the output signals of the measuring amplifiers are summed up phase by phase in a pulse-modulated manner in a summing amplifier. The duration of the pulses generated by the trip are controlled in accordance with the amplification factor of the respective associated measuring amplifier while the output of the summing amplifier represents a ground fault monitoring signal.

This application is the national phase under 35 U.S.C. § 371 of PCT International Application No. PCT/DE2004/001906 which has an International filing date of Aug. 24, 2004, which designated the United States of America and which claims priority on German Patent Application number 103 42 599.3 filed Sep. 11, 2003, the entire contents of which are hereby incorporated herein by reference.

### FIELD

The invention generally relates to a method and/or a circuit arrangement. For example, it may relate to one or the other for the detection of ground faults on electronic trips or releases for low-voltage power circuit breakers having upstream or serially connected measuring amplifiers.

### BACKGROUND

Low-voltage power circuit breakers may have other functions in addition to their main function, namely that of short-circuit current monitoring and overcurrent monitoring. These other functions include, as the most important function, that of ground-fault monitoring.

Ground faults may have serious consequences in electrical systems by them triggering fires, for example. These ground faults are therefore eliminated using power circuit breakers, which have a corresponding ground-fault detection function, with a time delay by the power circuit breaker being tripped, or the ground faults are at least indicated using signals.

In the case of two-pole or three-pole power circuit breakers, for this purpose vectorial summation is carried out of the phase currents and of the current in the neutral conductor, if a neutral conductor current transformer is provided. If a residual current is above a response value, a display is triggered and the power circuit breaker is tripped, if appropriate. As an alternative to this, a ground fault can also only be detected by an additional current transformer in the neutral conductor or at the grounded star point.

The ground-fault detection function can be implemented, for example, by a special module which can be inserted on the power circuit breaker, as is described in DE 694 25 916 T2.

The current measured by the current transformers is usually passed on to the tripping unit of the low-voltage power circuit breaker via measuring amplifiers. One problem with this is the fact that the measuring amplifiers have a high tolerance in terms of their gain factor. During the summation which is required for the purpose of detecting ground faults, the release can then measure a ground fault although the power supply system is free of ground faults. The reverse case is also conceivable, i.e. there is a ground fault but the total current is approximately zero.

In order to alleviate this problem, until now software-oriented correction has been carried out in the processor of the release. The current signals have then been summated in a software-oriented manner. However, it has been shown that this results in a considerable degree of error since the low ground-fault currents resulting in tripping only approximately correspond to two converter stages of the analog-to-digital converters of the electronic tripping unit, with the result that the phase currents are not reproduced precisely enough for the purpose of ground-fault detection.

### SUMMARY

At least one embodiment of the invention includes an object of specifying an electronic release for low-voltage power circuit breakers which allows for error-free detection of ground faults.

Accordingly, the output signals from the measuring amplifiers are passed on to a pulse-width-modulated summing amplifier. The three or four input signals are connected to the input of this summing amplifier via three or four analog switches. Owing to the selection of the respective duty factors of the analog switches, correction takes place which brings the gains for the inputs of the ground-fault measurement to the same desired factor.

One advantage of the circuit according to at least one embodiment of the invention is the fact that hardware-oriented compensation is dispensed with. The inaccuracies in the software-oriented addition are no longer present. The gain factors of the measuring amplifiers can be determined easily by an equal input signal being passed on to each current transformer in a test, and the measurement results then being stored in the microprocessor of the release. They can then be used directly in the determination of the duty factor.

### BRIEF DESCRIPTION OF THE DRAWINGS

Embodiments of the invention will be explained in more detail below by way of example with reference to the drawings, in which:

FIG. 1 shows an example of a circuit according to at least one embodiment of the invention, and

FIG. 2 shows a second variant of a circuit according to at least one embodiment of the invention.

### DETAILED DESCRIPTION OF THE EXAMPLE EMBODIMENTS

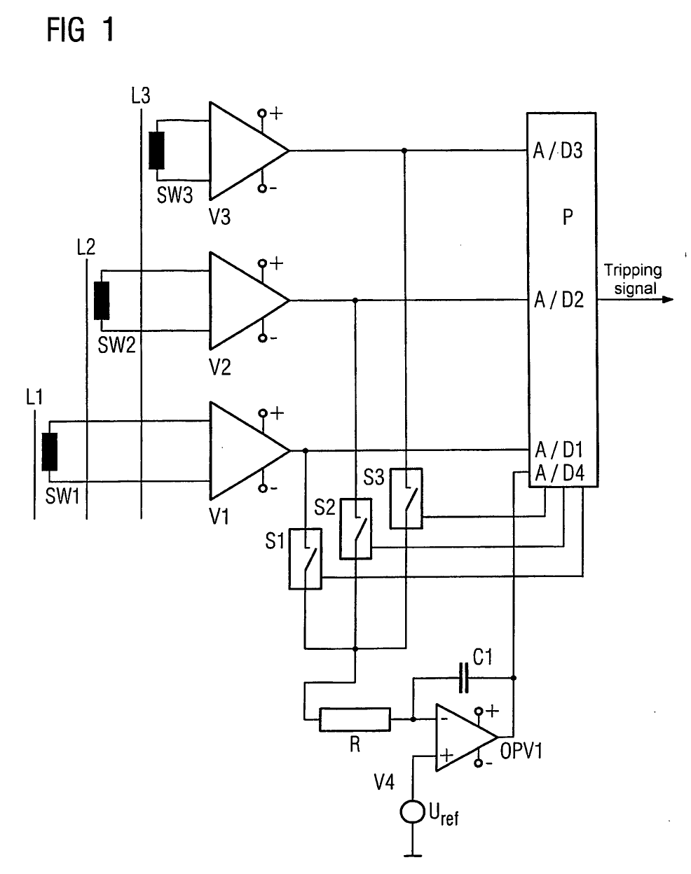

FIG. 1 shows a schematic of an electronic release on a three-phase power supply system. On the three conductors L1, L2, L3 of the power supply system, the currents are measured via current transformers SW1, SW2, SW3 and passed on to the measuring amplifiers V1, V2, V3, whose outputs are connected to analog-to-digital converters A/D1, A/D2, A/D3 of a microprocessor μP, which represents the essential functional part of the release.

According to at least one embodiment of the invention, the output signals from the measuring amplifiers V1, V2, V3 are passed on to switches S1, S2, S3, which are driven in a pulse-width-modulated manner by the microprocessor μP. The switches S1, S2, S3 (illustrated only schematically here) can be implemented, for example, by switching transistors. If one switch S1, S2, S3 is carrying a current, the others are open, in which case the duty factor corresponds to the gain factor of the respectively associated measuring amplifier V1, V2, V3.

The outputs of the switches S1, S2, S3 are connected to a point which represents the input of a summing amplifier V4 via a series resistor R. The summing amplifier V4 is implemented by an integrating circuit, i.e. by an operational amplifier OPV1, whose output is fed back to its input via a capacitor C1. Since the overall measurement varies within the DC range, the second input of the operational amplifier OPV1 is biased with a reference voltage Uref, which corresponds to the mean value for the voltage range of the measuring amplifiers V1, V2, V3. The output signal of the operational amplifier OPV1 is then passed on to an analog-to-digital converter A/D4 of the microprocessor μP and represents a signal for ground-fault monitoring.

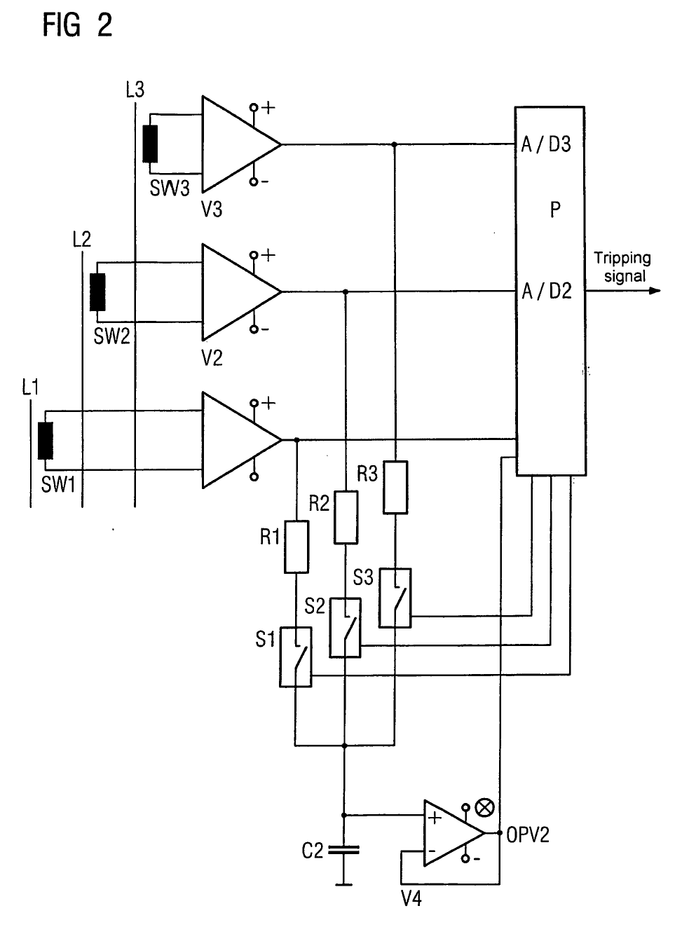

The circuit shown in FIG. 2 differs from the previously described variant only by the fact that the output signals from the measuring amplifiers V1, V2, V3 are passed on to the switches S1, S2, S3 via resistors R1, R2, R3, and the outputs of the switches S1, S2, S3 are connected directly to a capacitor C2, which reproduces the total current of the phase currents of the conductors L1, L2, L3. This signal is passed on to the analog-to-digital converter A/D4 of the microprocessor μP via an operational amplifier OPV2.

Example embodiments being thus described, it will be obvious that the same may be varied in many ways. Such variations are not to be regarded as a departure from the spirit and scope of the present invention, and all such modifications as would be obvious to one skilled in the art are intended to be included within the scope of the following claims.

1. A method for low-voltage power circuit breakers connected to measuring amplifiers, the method comprising:
summing the output signals from the measuring amplifiers, in a manner which is pulse-modulated in terms of phase, in a summing amplifier, the duration of the pulses being controlled by a release as a function of the gain factor of the respectively associated measuring amplifier, and the output of the summing amplifier representing a signal for ground-fault monitoring.

2. A circuit arrangement for the detection of ground faults on electronic releases for low-voltage power circuit breakers connected to measuring amplifiers comprising:
switches drivable in a pulse-width modulated manner by the release on the basis of the gain factors of the measuring amplifiers and connected to, in each case, one output of a measuring amplifier outputs of the switches together being connected to the input of a summing amplifier, whose output represents a signal for ground-fault monitoring.

3. The circuit arrangement as claimed in claim 2, wherein
the summing amplifier is an integrating amplifier, comprising an operational amplifier having capacitive feedback, whose second input is biased with a reference voltage, which corresponds to the mean value for the voltage range of the measuring amplifiers.

4. The circuit arrangement as claimed in claim 2,
wherein the summing amplifier is implemented by a capacitor having a downstream amplifier.

5. A method for ground fault monitoring on electronic releases for a low-voltage power circuit breakers connected to measuring amplifiers, the method comprising:
summing the output signals from the measuring amplifiers, in a manner which is pulse-modulated in terms of phase, duration of the pulses being controlled by a release as a function of the gain factor of the respectively associated measuring amplifier; and
outputting a summed signal for ground-fault monitoring.

6. An arrangement for ground fault monitoring on electronic releases for a low-voltage power circuit breakers connected to measuring amplifiers, the method comprising:
means for summing the output signals from the measuring amplifiers, in a manner which is pulse-modulated in terms of phase, duration of the pulses being controlled by a release as a function of the gain factor of the respectively associated measuring amplifier; and
means for outputting a summed signal for ground-fault monitoring.

7. The arrangement as claimed in claim 6, wherein the means for summing includes an integrating amplifier, comprising an operational amplifier having capacitive feedback, whose second input is biased with a reference voltage, which corresponds to the mean value for the voltage range of the measuring amplifiers.

8. The arrangement as claimed in claim 6, wherein the means for summing is implemented by a capacitor having a downstream amplifier.
